(19) United States
(12) Patent Application Publication
(10) Pub. No.: US 2024/0222063 A1
(43) Pub. Date: Jul. 4, 2024

(54) CHARGED PARTICLE BEAM COLUMN, CHARGED PARTICLE BEAM CHROMATIC ABERRATION CORRECTOR, AND METHOD OF CORRECTING CHARGED PARTICLE BEAM CHROMATIC ABERRATION

(71) Applicant: ICT Integrated Circuit Testing Gesellschaft für Halbleiterpüftechnik mbH, Heimstetten (DE)

(72) Inventors: John Breuer, München (DE); Pieter Kruit, Delft (NL)

(73) Assignee: ICT Integrated Circuit Testing Gesellschaft für Halbleiterpüftechnik mbH, Heimstetten (DE)

(21) Appl. No.: 18/091,808

(22) Filed: Dec. 30, 2022

(51) Int. Cl. H01J 37/153; H01J 37/26

(52) U.S. Cl. CPC H01J 37/153; H01J 37/265; H01J 2237/1534

(57) ABSTRACT

A charged particle beam chromatic aberration corrector is described. The charged particle beam chromatic aberration corrector includes a plurality of electrical conductors forming a segmented Wien filter including a plurality of Wien filter segments having at least a first Wien filter segment and a second Wien filter segment, wherein the first Wien filter segment is arranged for traversal of a first portion of the charged particle beam, and the second Wien filter segment is arranged for traversal of a second portion of the charged particle beam; and a power supply system configured for generating different electric fields and different magnetic fields for the first Wien filter segment and second Wien filter segment.

### TECHNICAL FIELD

Embodiments described herein relate to charged particle beam chromatic aberration correctors, particularly in a charged particle beam column, such as an electron microscope or a scanning electron microscope. Further embodiments relate to charged particle beam columns for inspecting and/or imaging a sample and having a chromatic aberration corrector. Still further embodiments relate to methods for correcting chromatic aberration of a charged particle beam, particularly in a charged particle beam column.

### BACKGROUND

Modern semiconductor technology has created a high demand for structuring and probing specimens in the nanometer and sub-nanometer scale. Micrometer and nanometer-scale process control, such as inspection or structuring, is often done with charged particle beams, e.g. electron beams, which are generated, shaped, deflected and focused in charged particle beam columns, such as electron microscopes or electron beam pattern generators. For inspection purposes, charged particle beams typically achieve better spatial resolutions than photon beams.

Inspection apparatuses using charged particle beams such as scanning electron microscopes have numerous uses in many industrial applications, including inspection of electronic circuits, exposure systems for lithography, detection systems, defect inspection tools, and testing systems for integrated circuits. In charged particle beam systems, fine beam probes with high current density may be used. For example, in scanning electron microscopes, primary electron beam generating signal particles such as secondary electrons and backscattered electrons may be used to image and inspect a sample.

Reliable inspection and imaging of samples with charged particle beam systems at a good resolution is challenging because charged particle beams suffer from beam aberrations which limit resolution. In charged particle beam systems, aberration correctors may be provided for at least partially compensating one or more aberrations, such as spherical aberration, astigmatism, and chromatic aberration. An aberration-corrected charged particle beam may achieve a smaller probe spot size, improved focus and superior resolution as compared to an uncorrected beam.

Several methods for correcting aberrations of a charged particle beam in electron microscopes have been described. For example, one of the aberrations is the chromatic aberration Cc, wherein different methods of correcting chromatic aberrations have been proposed with multipole correctors or mirror correctors.

In view of the above, it would be beneficial to provide improved charged particle beam aberration correctors and improved methods of correcting charged particle beam aberrations, particularly in charged particle beam columns. It would be beneficial to provide methods which have low voltage requirements, low current losses, or both. Further, it would be beneficial to provide charged particle beam systems for inspecting and/or imaging a sample that is configured for being operated in accordance with any of the methods described herein. Further, it would be beneficial to provide charged particle beam aberration correctors, particularly in charged particle beam columns, with low voltage requirements and allowing for high currents.

### SUMMARY

In view of the above, charged particle beam chromatic aberration correctors, particularly in a charged particle beam column, charged particle beam columns having a chromatic aberration corrector and methods for correcting chromatic aberration of a charged particle beam, particularly in a charged particle beam column are provided.

According to an embodiment, a charged particle beam chromatic aberration corrector is provided. The charged particle beam chromatic aberration corrector includes a plurality of electrical conductors forming a segmented Wien filter including a plurality of Wien filter segments having at least a first Wien filter segment and a second Wien filter segment, wherein the first Wien filter segment is arranged for traversal of a first portion of the charged particle beam, and the second Wien filter segment is arranged for traversal of a second portion of the charged particle beam; and a power supply system configured for generating different electric fields and different magnetic fields for the first Wien filter segment and second Wien filter segment.

According to an embodiment, a charged particle beam chromatic aberration corrector is provided. The charged particle beam chromatic aberration corrector includes a first set of wires forming two or more openings including a first opening in a first Wien filter segment and a second opening in a second Wien filter segment, at least the first Wien filter segment and the second Wien filter segment forming a first segmented Wien filter for a charged particle beam, wherein the first opening is arranged for traversal of a first portion of the charged particle beam, and the second opening is arranged for traversal of a second portion of the charged particle beam; and a first set of current loop forming wires including a first current loop forming wire of the first Wien filter segment and a second current loop forming wire of the second Wien filter segment.

According to an embodiment, a charged particle beam chromatic aberration corrector is provided. The charged particle beam chromatic aberration corrector includes a plurality of electrical conductors forming two or more openings including a first opening in a first Wien filter segment and a second opening in a second Wien filter segment; wherein a first electrical conductor and a second electrical conductor of the plurality of electrical conductors extend in a direction perpendicular to a plane of the first opening and the second opening; and wherein the first Wien filter segment is arranged for traversal of a first portion of a charged particle beam through the first opening and the second Wien filter segment is arranged for traversal of a second portion of the charged particle beam through the second opening; wherein the first electrical conductor bounds the first opening and the second electrical conductor bounds the second opening.

According to an embodiment, a method of correcting chromatic aberration of a charged particle beam using a corrector according to of the embodiments described herein, the method includes: generating a respective one of a plurality of electric fields and a respective one a plurality of magnetic fields in each of the two or more openings; and guiding the charged particle beam through the two or more openings.

Further aspects, advantages and features of the present disclosure are apparent from the description and the accompanying drawings.

### BRIEF DESCRIPTION OF THE DRAWINGS

A more particular description of embodiments, as briefly described above, may be had by reference to the accompanying drawings which are briefly described as follows.

FIG. 1 illustrates a charged particle column having a chromatic aberration corrector according to embodiments described herein.

FIG. 2A is a schematic view of an exemplary segmented Wien filter having a first Wien filter segment for a first portion of a charged particle beam and a second Wien filter segment for a second portion of the charged particle beam according to embodiments described herein.

FIG. 2B is a schematic view of an exemplary segmented Wien filter having a first Wien filter segment for a first portion of a charged particle beam and a second Wien filter segment for a second portion of the charged particle beam according to embodiments described herein, wherein two regions with electric fields are provided.

FIG. 3 is a schematic view of an exemplary segmented Wien filter having a first Wien filter segment for a first portion of a charged particle beam and a second Wien filter segment for a second portion of the charged particle beam according to embodiments described herein.

FIG. 4 is a partial view of a grid-type chromatic aberration corrector, in particular, having a segmented Wien filter in x-direction and in y-direction, according to examples described herein.

FIG. 5 is a top view of the grid-type chromatic aberration corrector of FIG. 4, wherein the top segmented Wien filter is shown according to examples described herein.

FIG. 6 is a simplified schematic of an exemplary cylinder-type chromatic aberration corrector according to embodiments described herein.

FIG. 7 is a simplified representation of a chromatic aberration corrector according to aspects described herein.

FIG. 8 is a flow diagram of a method of correcting chromatic aberration of a charged particle beam according to aspects described herein.

FIG. 9 is a method of correcting chromatic aberration according to embodiments described herein.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

A main limiting factor for resolution of electron microscopes, e.g. scanning electron microscopes, is aberrations of the probe electron beam. One of the major aberrations is chromatic aberration, Cc. Chromatic aberration may be understood as an energy-dependent focusing of the electron-beam.

According to aspects, embodiments and examples described herein, Wien filter coaxial deflectors can be built to create (logarithmically changing) energy-dependent phase shifts, which can approximate a desired phase shift very well, for example, to correct the chromatic aberration.

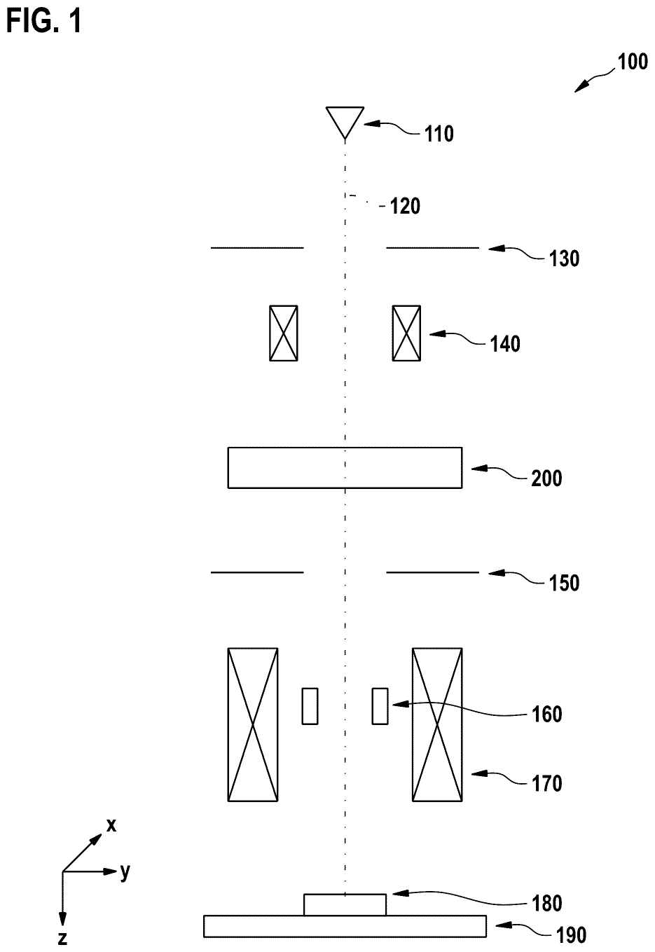

Some elements of a charged particle column, as illustrated in at least FIG. 1, are described further as follows. FIG. 1 illustrates a charged particle column having a chromatic aberration corrector according to aspects, embodiments and examples described herein.

In an exemplary embodiment, a charged particle beam column 100 includes a sample stage 190; a charged particle beam manipulation system including the charged particle beam chromatic aberration corrector 200; and a charged particle source 110 configured for generating the charged particle beam. The charged particle beam column 100 can be of a charged particle system. In an example, the charged particle system is an electron microscope, e.g. a scanning electron microscope. In an example, the charged particle beam system is configured for inspecting a sample 180, e.g. a surface region of the sample 180. The charged particle beam column 100 is configured for imaging (a surface of) a sample 180, for measuring one or more dimensions of one or more features of a sample 180, for performing critical dimension measurement on a sample 180, for detecting defects, and/or for evaluating a quality of a sample 180.

In an embodiment, the charged particle beam column 100 includes a charged particle source 110 for emitting a charged particle beam. In an example, the charged particle source 110 is an electron source. An anode 130 can be provided. The charged particle beam can be an electron beam. In an example, the charged particle beam is a primary charged particle beam.

In an embodiment, the charged particle beam column 100 includes an axis 120. The axis 120 may be an axis of the charged particle beam column 100, an axis of the charged particle beam, an axis of the aberration corrector 200, and/or an axis aligned with an axis of the aberration corrector 200. In an example, the axis 120 is an axis along which or parallel to which the charged particle beam propagates. In an example, the charged particle beam propagates in the charged particle beam column 100 along or parallel to the axis 120 from a charged particle source 110. In an example, the charged particle beam propagates in the charged particle beam column 100 along or parallel to the axis 120 towards a sample 180 and/or to impinge on a sample 180.

The charged particle beam column 100 can include a condenser lens 140. In an example, the condenser lens 140 is arranged downstream of the charged particle source 110. The condenser lens 140 is configured for collimating a charged particle beam, e.g. the charged particle beam being emitted from the charged particle source 110 and/or the charged particle beam.

In an embodiment, the charged particle beam column 100 and/or charged particle system includes the aberration corrector 200. In an example, the aberration corrector 200 is configured for correcting a chromatic aberration of the charged particle beam.

In an example, the charged particle beam column 100 includes a charged particle detector 150. In an example, the charged particle detector 150 is an electron detector. In an example, charged particle detector 150 is configured for receiving and/or detecting signal particles, e.g. as a function of a (landing) position of the charged particle beam on a sample 180 and/or focal position of a focusing lens 170. Signal particles can be secondary electrons, backscattered electrons, Auger electrons and/or X-rays. It may be understood that a charged particle beam impinging on a sample produces signal particles. It may be understood that signal particles are emitted from the sample 180. In an example, signal particles are emitted from a sample 180 when a charged particle beam impinges on the sample 180. It may be understood that signal particles provide information about spatial characteristics and/or dimensions of one or more features of a sample 180.

In an example, the charged particle beam column 100 and/or charged particle system includes an image generation unit (not shown) configured for generating an image of the sample 180 based on signal particles received and/or detected at a charged particle detector. In an example, the charged particle beam column 100 and/or charged particle system includes a processing unit (not shown) configured for receiving and/or processing the image of the sample 180 from the image generation unit. The processing unit can be configured for determining a beam aberration coefficient value.

The charged particle beam column 100 can include a scan deflector 160. In an example, the scan deflector 160 is configured for scanning a charged particle beam, in particular, over a surface of a sample 180. The scan deflector 160 is configured for scanning the charged particle beam in a direction perpendicular to the axis 120 and/or an X-direction and/or a Y-direction. In an example, scanning a charged particle beam over a surface of a sample 180, e.g. with a scan deflector 160, and detecting signal electrons, e.g. as a function of the generation position of the signal electrons, the surface of the sample 180 or a portion thereof is thereby imaged, for example using an image generation unit configured to provide an image of the sample 180 based on received signal electrons.

The charged particle beam column 100 shown in FIG. 1 includes a focusing lens 170. The focusing lens 170 can be an objective lens. In an example, the focusing lens 170 is configured for focusing the charged particle beam, e.g. on a (surface of) sample 180. In an embodiment, the focusing lens 170 is a magnetic lens, an electrostatic lens, or a magnetic-electrostatic lens. In an example, inspecting a sample 180 with a charged particle beam may include focusing the charged particle beam on a surface of a sample 180 with a focusing lens 170. In an example, a sample 180 is a substrate, having one or more layers and/or features formed thereon. A sample 180 may be a semiconductor wafer, a glass substrate, a flexible substrate such as a web substrate, or a sample that is to be inspected.

The charged particle beam column 100 and/or charged particle system can include a sample stage 190. In an example, the sample stage 190 is configured for supporting a sample 180. The sample can be arranged on a sample stage 190. In an example, the sample stage 190 is configured for being movable. In an embodiment, the sample stage 190 is configured for being movable in a direction parallel to the axis 120 and/or a Z-direction. In an example, the sample stage 190 is configured for being movable such that a distance between the focusing lens 170 and the sample stage 190 is adjustable.

The charged particle beam column 100 and/or charged particle system can include a vacuum chamber (not shown). The vacuum chamber is configured evacuate the charged particle beam column 100 and/or charged particle system. The vacuum chamber is configured for reducing a pressure in the charged particle beam column 100 and/or charged particle system such that the charged particle beam is in sub-atmospheric pressure. A sub-atmospheric pressure may be understood as a pressure below 10⁻³ mbar or below 10⁻⁵ mbar.

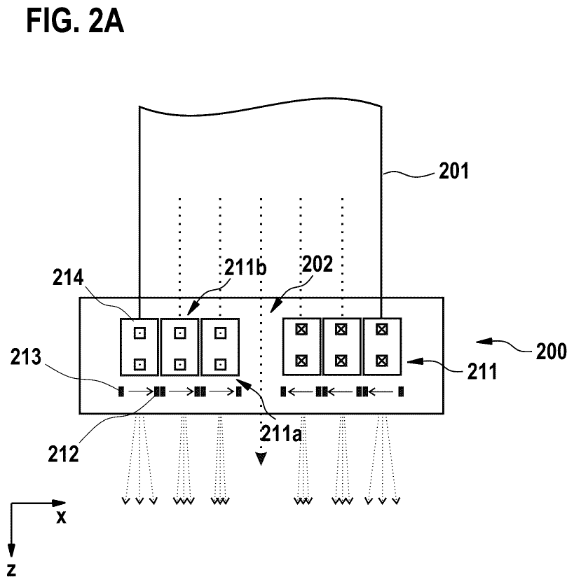

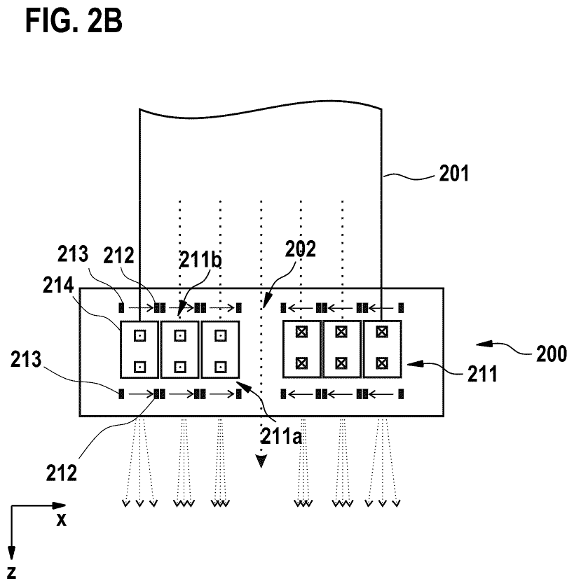

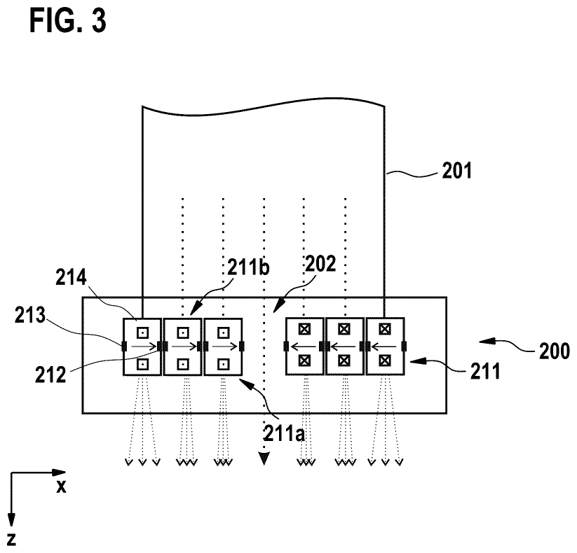

Some elements of a chromatic aberration corrector, which may be described (in a non-limiting manner) as having a grid form or a grid-type corrector, and as illustrated in at least FIG. 2A, FIG. 2B and FIG. 3, are described further as follows. FIG. 2A, FIG. 2B and FIG. 3 are simplified schematics of exemplary grid-type chromatic aberration correctors according to aspects, embodiments and examples described herein.

FIG. 2A shows a charged particle beam chromatic aberration corrector 200. A charged particle beam 201 travels through the chromatic aberration corrector, wherein different portions of the charged particle beam experience different dispersion in a plurality of Wien filter segments in the segmented Wien filter 211. The segmented Wien filter 211 includes a plurality of Wien filters or Wien filter segments, in particular a plurality of Wien filters for different or respective portions of the charged particle beam 201. For example, a first Wien filter segment 211a is disposed adjacent to a central opening 202. The first Wien filter segment 211a can be at a first distance to the axis of the corrector and/or to a center or axis of the charged particle beam 201. A second Wien filter segment 211b is provided adjacent to the first Wien filter segment 211a. The second Wien filter segment 211b can be at a second distance to the axis of the corrector and/or to a center or axis of the charged particle beam 201, wherein the first distance is smaller than the second distance. For example, the distance can be defined in the direction of dispersion of the Wien filter segments.

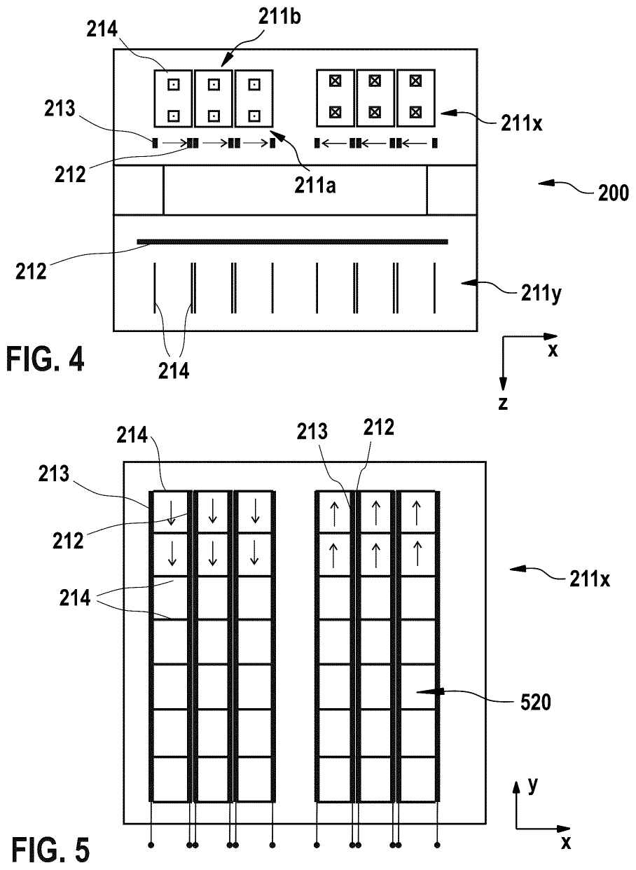

The plurality of Wien filters segments is formed by a plurality of electrical conductors, such as a plurality of wires. As indicated for one of the Wien filter segments of the segmented Wien filter 211, a first wire 212 and a second wire 213 can be provided to generate an electric field as indicated by the arrows in FIG. 2A. The electric fields shown in FIG. 2A are exemplarily shown for charged particles that are electrons. The plurality of wires can be provided to generate electric fields in x-direction. A wire grid, as exemplarily shown in FIGS. 4 and 5, may provide an electric field in x-direction and in y-direction. According to some embodiments, which can be combined with other embodiments described herein, the wires generating an electric field in x-direction can be in a different plane (along the z-direction, i.e. along an optical axis, than the wires generating an electric field in y-direction. The plurality of Wien filter segments is provided for one charged particle beam. Accordingly, a portion of a charged particle beam passes through a Wien filter segment in the center of the Wien filter segment but also at an edge region of the Wien filter segment. Thus, conductors of the Wien filter segments acting in x-direction and Wien filter segments acting in y-direction are beneficially spaced apart in z-direction, i.e. are provided in a different plane. According to some embodiments, the plurality of conductors form a plurality of openings including a first opening and a second opening. The openings are configured for trespassing of respective portions of the charged particle beam.

The Wien filter segments of the segmented Wien filter 211 include a current loop forming wire 214. The magnetic fields shown in FIG. 2A by the symbols depicted with squares (with a dot or cross inside) are generated by the current loop forming wires. The magnetic fields shown in FIG. 2A are exemplarily shown for charged particles that are electrons.

According to one embodiment, a charged particle beam chromatic aberration corrector is provided. The charged particle beam chromatic aberration corrector includes a plurality of electrical conductors forming two or more Wien filter segments including a first Wien filter segment and a second Wien filter segment. For example, the plurality of conductors can form two or more openings including a first opening corresponding to the first Wien filter segment and a second opening corresponding to the second Wien filter segment. An opening as referred to herein may be provided between two parallel wires for chromatic aberration correction in one dimension. For chromatic aberration correction, an opening may also be referred to as an opening between parallel wires in x-direction and parallel wires y-direction, wherein the opening is formed by a projection in one plane, i.e. parallel wires in x-direction and parallel wires in y-direction are projected in the same plane.

FIGS. 2A to 5 show two wires for each opening, i.e. for neighboring openings two adjacent wires are shown. According to some embodiments, which can be combined with other embodiments described herein, the wires creating the electric fields for the different openings can be shared by neighboring openings. For example, in FIG. 5, instead of a separation between the first wire 212 and the second wire 213, one wire can be provided. A wire between the neighboring openings can be at a fixed potential. A voltage increase with increasing distances from the center can be provided by one wire between neighboring openings.

The first Wien filter segment is arranged for traversal of a first portion of the charged particle beam, and the second Wien filter segment is arranged for traversal of a second portion of the charged particle beam. A power supply system is configured for generating different electric fields and different magnetic fields for the first Wien filter segment and second Wien filter segment.

According to embodiments of the present disclosure a Wien filter is understood as an element providing a crossed electric field and magnetic field (Ex B). Thus, a Wien filter is a device consisting of perpendicular electric and magnetic fields that can in many applications be used as a velocity filter for charged particles. The Wien filter generates a dispersion, which creates a deflection as a function of the velocity of the charged particles, i.e. the energy of the charged particles. Each Wien filter segment of the segmented Wien filter can provide different dispersion for respective portions of the charged particle beam. A chromatic aberration corrector is provided.

According to some embodiments, which can be combined with other embodiments described herein, the two or more Wien filter segments each include a first region having a magnetic field, a second region having an electric, wherein the electric field acts in an opposite direction as the magnetic field. The first region and the second region are displaced along the optical axis, i.e. in z-direction in FIG. 2A. In the example shown in FIG. 2A, the first region can be an upper region with respect to the z-direction and the second region can be a lower region with respect to the z-direction. According to some embodiments, which can be combined with other embodiments described herein, the wires generating an electric field can be in a different plane as compared to loop forming wires 214 to avoid an influence of the loop forming wires on the electric field.

FIG. 2A show electrical conductors, for example, the first wire 212 and a second wire 213, below the current loop forming wires 214. FIG. 2B additionally shows conductors configured to generate an electric field above the current loop forming wires 214. Accordingly, an electric field is provided above and below the magnetic field generated by the current loop forming wires. For example, the Wien filter segments can be operated with a symmetric arrangement of electric fields and magnetic fields. The electric field above the current loop forming wire can be about 50% of the electric field of the Wien filter segment shown in FIG. 2A and the electric field below the current loop forming wire can be about 50% of the electric field of the Wien filter segment shown in FIG. 2A. The symmetric arrangement of the Wien filter segments allows to reduce or can avoid a displacement of the portions of the electron beam within a Wien filter segment.

According to a yet further implementation, as exemplarily shown in FIG. 3, the conductors configured to generate electric fields in the Wien filter segments, for example, the first wire 212 and a second wire 213 of the Wien filter segment, may be provided at the center of the current loop forming wires 214 or between an upper conductor and a lower conductor of the current loop forming wires 214. Providing the wires for generating an electric field away from an upper conductor and lower conductor, allows for generating the electric field without the current loop forming wire disturbing the electric field generation. For example, the Wien filter segments can be operated with a symmetric arrangement of electric fields and magnetic fields. The symmetric arrangement of the Wien filter segments allows to reduce or can avoid a displacement of the portions of the electron beam within a Wien filter segment.

With reference to FIG. 2B, according to some embodiments, which can be combined with other embodiments described herein, the two or more Wien filter segments each include a first region having an electric field, a second region having a magnetic field, and a third region having an electric field, wherein the electric fields act in an opposite direction as the magnetic field. The first region, the second region, and the third region are displaced along the optical axis, i.e. in z-direction in FIG. 2B.

With reference to FIG. 3, according to some embodiments, which can be combined with other embodiments described herein, the two or more Wien filter segments each include a first region having a magnetic field, a second region having an electric field, wherein the electric field acts in an opposite direction as the magnetic field. The second region can be within the first region, and may e.g. be centered in the first region. The second region having the electric field is displaced in z-direction away from an upper end and a lower end of the first region having the magnetic field.

FIG. 4 and FIG. 5 show a charged particle beam chromatic aberration corrector 200. The charged particle beam chromatic aberration corrector 200 includes a plurality of wires or a plurality of conductors, respectively, forming a segmented Wien filter including a plurality of Wien filter segments. The plurality of wires includes wires configured to generate an electric field of the Wien filter segment, for example, a first wire 212 and the second wire 213. The plurality of wires includes current loop forming wires 214. A plurality of openings 520 are provided by the plurality of wires. For example, a first opening of the plurality of openings is arranged for traversal of a first portion of the charged particle beam and a second opening of the plurality of openings is arranged for traversal of a second portion of the charged particle beam. Different Wien filter segments are provided for different portions of the charged particle beam.

The wires configured to generate an electric field for each of the Wien filter segments extend in a first plane perpendicular, or essentially perpendicular, to an axis of the charged particle beam. According to some embodiments, which can be combined with other embodiments described herein, a plane of the current loop forming wires, i.e. the plane of the loops formed by the wire, is perpendicular or essentially perpendicular to the first plane.

FIG. 4 shows a segmented Wien filter 211x acting in an x-direction, i.e. a first direction. The Wien filter 211x corresponds to the Wien filter shown in FIG. 2A. However, also implementations according to FIG. 2B or FIG. 3 can be provided as the segmented Wien filter 211x. A first set of wires configured to generate the electric fields of the Wien filter segments, for example, a first wire 212 and a second wire 213, of the segmented Wien filter 211x extend in the y-direction, i.e. a second direction. A segmented Wien filter 211y is provided, which acts in the y-direction. A second set of wires configured to generate the electric fields of the Wien filter segments of the segmented Wien filter 211y extend in the x-direction, i.e. a first direction. The first direction and the second direction can be perpendicular. According to some embodiments, which can be combined with other embodiments described herein, the segmented Wien filter 211y has the same structural details as compared to the segmented Wien filter 211x and is rotated by 90° rotated, particularly rotated around an axis of the charged particle beam. The axis of the charged particle beam may also be considered as the axis of the charged particle beam column and/or in excess of the chromatic aberration corrector 200. For example, the axis 120 is shown in FIG. 1. In an example, the axis of the aberration corrector can be collinear with an axis of the charged particle beam column and/or with nexus of the charged particle beam.

The current loop forming wires 214 of the segmented Wien filter 211x are formed in loops extending in the x-z-plane. The current loop forming wires 214 of the segmented Wien filter 211y are formed in loops extending in the y-z-plane. In each of the segmented Wien filters, electric fields and magnetic fields are generated that are perpendicular to each other. The magnetic fields of the Wien filter segments in the segmented Wien filter 211x extend in the y-direction. Some of the magnetic fields are indicated by the arrows in FIG. 5. The magnetic fields of the Wien filter segments in the segmented Wien filter 211y extend in the x-direction. FIG. 5 shows a top view of the corrector shown in FIG. 4, wherein only the wires and current loop forming wires of the segmented Wien filter 211x are illustrated.

According to some embodiments, which can be combined with other embodiments described herein, a central opening without wires for electric field generation and without current loop forming wires can be provided. For example, FIG. 2A shows the central opening 202. Accordingly, an improved transparency of the charged particle beam chromatic aberration corrector for the charged particle beam can be provided. The central portion of the charged particle beam does not intersect with one of the plurality of wires or electrical conductors.

The two or more Wien filter segments can each include at least a first region having a magnetic field, a second region having an electric, wherein the electric field acts in an opposite direction as the magnetic field. For example, FIG. 4 shows a first region with respect to the z-direction, in which the magnetic fields of the current loop forming wires 214 are provided for the segmented Wien filter 211x and a second region with respect to the z-direction, in which the electric fields of the wires (e.g. first wire 212 and second wire 213) are provided for the segmented Wien filter 211x. Further, FIG. 4 shows a third region with respect to the z-direction, in which the electric fields of the wires are provided for the segmented Wien filter 211y, and a fourth region with respect to the z-direction, in which the magnetic fields of the currently forming wires are provided for the segmented Wien filter 211y. The first region, the second region, the third region and the fourth region are displaced along the optical axis, i.e. in z-direction. Advantageously, the electric fields generated in the second region and the third region are not deteriorated by crossing wires in the same z-plane. According to some embodiments, as exemplarily shown in FIG. 3, some of the regions may partly overlap. The plurality of wires is arranged to be electrically isolated from each other or not in electrical conduction with each other.

A first Wien filter segment is formed (in a first opening and/or proximate to a first opening) by at least two wires of the plurality of wires and first current loop forming wires. A second Wien filter segment is formed (in a second opening and/or proximate to a second opening) by at least two wires of the plurality of wires and second current loop forming wires.

As exemplarily shown in FIG. 4, a chromatic aberration corrector may have in one direction, i.e. x-direction or y-direction, outward electric field forces and inward magnetic field forces for one of the segmented Wien filters. Particularly, the forces can be inward or outward, respectively, for both, the x-direction and the y-direction. In an embodiment, a first electric field is formed in a first opening by an electric potential difference between at least two wires of the plurality of wires, e.g. for one of the segmented Wien filters. A second electric field is formed in a second opening by an electric potential difference between at least two wires of the plurality of wires. An electric field (in an opening and/or in a plane of an opening), particularly for a negatively charged particles like electrons, can be in an inwards direction and/or in a direction towards a center of the aberration corrector 200, particularly when considering one of the x-direction and the y-direction, i.e. when considering the directions separately.

According to some embodiments, which can be combined with other embodiments described herein, an electric potential of a wire is less or less positive than an electric potential of another wire that is further away from the central opening, particularly when considering that x-direction and the y-direction separately, i.e. for the segmented Wien filter 211x and for the segmented Wien filter 211y. Accordingly, going outward from the central opening, for example, in x-direction in FIG. 4, the potentials of the wires configured to generate electric fields becomes more positive. In an exemplary embodiment, (the aberration corrector 200 is configured to generate, e.g. by a power supply system) an electric field exerting an electric force on a portion of a charged particle beam in an outward direction (e.g. for one of the x-direction or the y-direction) or a radially outwards direction.

Further, a first magnetic field is formed in a first opening by a first current in a current loop forming wire, e.g. for one of the segmented Wien filters. A second magnetic field is formed in a second opening a second current in a current loop forming wire, e.g. for the one of the segmented Wien filters. A magnetic field force (in an opening and/or in a plane of an opening), particularly for a negatively charged particles like electrons, can be in an inward direction and/or in a direction towards from a center of the aberration corrector 200, particularly when considering one of the x-direction and the y-direction, i.e. when considering the directions separately.

According to some embodiments, which can be combined with other embodiments described herein, going outward from the central opening, for example, in x-direction in FIG. 4 for the segmented Wien filter 211x, the magnetic field strengths generated by the current loops formed by the current loop forming wires 214 increase. The same applies for the y-direction for the segmented Wien filter 200y. In an embodiment, a magnetic field force of a Wien filter segment on a portion (or on a respective portion) of a charged particle beam is in an opposite direction to an electric field force on said portion (or said respective portion) of a charged particle beam, particularly in said opening (or in each opening), i.e. between two of the wires to generate the electric fields.

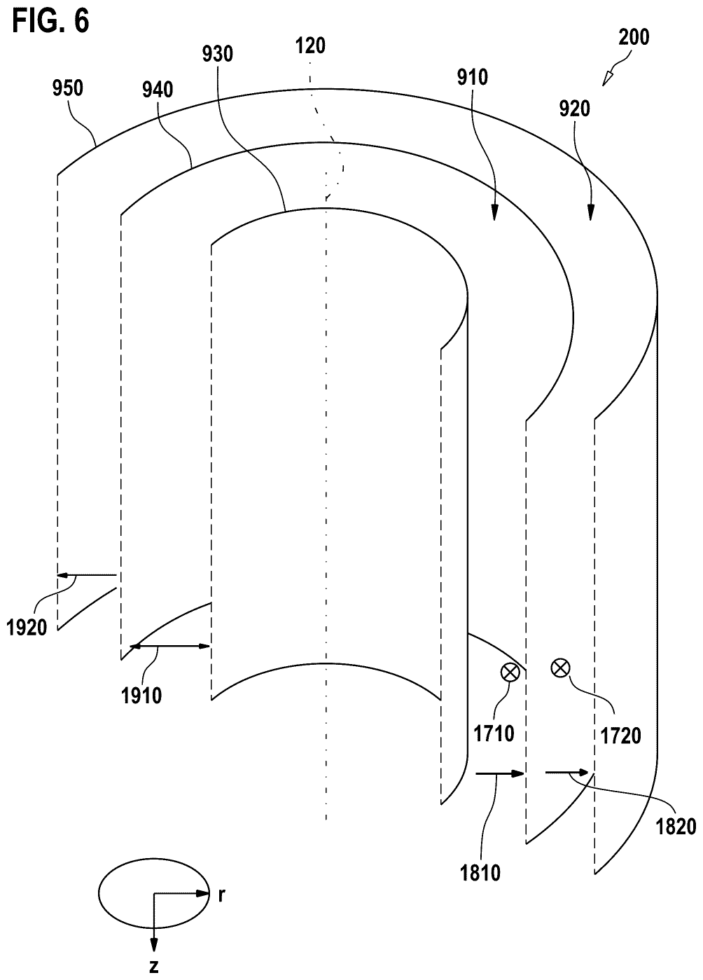

According to embodiments described herein, a chromatic aberration corrector can have electric and/or magnetic field or field strength as an (inverse or inversely proportional or reciprocal) function of a distance from the center or the center opening in one direction (e.g. the x-direction for segmented Wien filter 211x or the y-direction for the segmented Wien filter 211y). For a cylindrical segmented Wien filter as described with respect to FIG. 6, the chromatic aberration corrector can have electric and/or magnetic field or field strength as an (inverse or inversely proportional or reciprocal) function of the radius. Different magnetic field strengths and different magnetic field strength can be provided for different Wien filter segments.

According to some embodiments, which can be combined with other embodiments described herein, the dispersions introduced by the various Wien filter segments provide an increase, particularly a linear increase, in dispersion from the center or center opening towards the outer side of the corrector, e.g. in one of the x-direction or y-direction, or radially for a cylindrical segmented Wien filter. For example, the first set of wires extending in y-direction and/or the second set of wires extending in x-direction can be equidistant.

A chromatic aberration corrector, which may be described as having cylindrical form, as may be understood from FIG. 6, is described further as follows. FIG. 6 is a simplified schematic of an exemplary cylinder-type chromatic aberration corrector according to embodiments described herein.

According to an aspect, there is provided a charged particle beam chromatic aberration corrector 200 including a plurality of electrical conductors 930, 940, 950 forming two or more openings including a first opening 910 and a second opening 920.

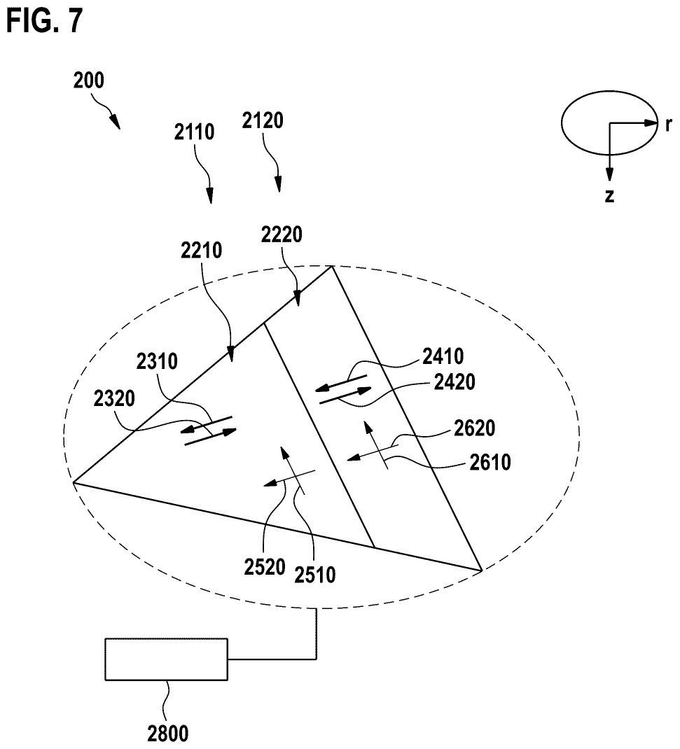

According to the aspect, the first electrical conductor 930 and the second electrical conductor 940 extend in a direction perpendicular to the plane of the first opening 910 and the second opening 920; the first opening 910 is arranged for traversal of a first portion 2110 (see for example FIG. 7) of the charged particle beam, and the second opening 920 is arranged for traversal of a second portion 2120 (see for example FIG. 7) of the charged particle beam.

According to the aspect, the plurality of electrical conductors 930, 940, 950 include a first electrical conductor 930 bounding the first opening 910, and a second electrical conductor 940 bounding the second opening 920. In an embodiment, the plurality of electrical conductors 930, 940, 950 include a third electrical conductor 950 bounding the second opening 920. According to the aspect, at least one of the plurality of electrical conductors 930, 940, 950 has a hollow cylindrical form or one or more sectors of a cylinder. According to the aspect, each of the plurality of electrical conductors 930, 940, 950 is coaxial with each other. For example, each of the plurality of electrical conductors 930, 940, 950 is coaxial with an axis of the charged particle beam.

In an embodiment, the first opening 910 is at a different or smaller radial position than the second opening 920. The first opening 910 can be bounded by two electrical conductors of the plurality of electrical conductors 930, 940, 950. The second opening 920 can be bounded by two electrical conductors of the plurality of electrical conductors 930, 940, 950, which are at different electric potential to each other. In an example, there may be a central opening coaxial with an axis 120.

In an embodiment, a first electric field 1810 across the first opening 910 is different or weaker than a second electric field 1820 across the second opening 920. An electric potential difference or an electric potential difference per distance across the first opening 910 can be different or smaller in magnitude than an electric potential difference or an electric potential difference per distance across the second opening 920. In an example, the conductors can be radially equidistant, i.e. a radial dimension or an annular radius 1910 of the first opening 910 is the same as a radial dimension or an annular radius 1920 of the second opening 920. In another example, a radial dimension or an annular radius of the first opening can be different or larger than a radial dimension or an annular radius of the second opening. According to some embodiments, which can be combined with other embodiments described herein, dispersions introduced by the various Wien filter segments provide an increase in dispersion, particularly a linear increase in dispersion, from the center or center opening outwardly.

In an embodiment, a first magnetic field 1710 across the first opening 910 is different or weaker than a second magnetic field 1720 across the second opening 920. A magnetic field strength in the first opening 910 (at a mid-point or center of the first opening 910) can be different or smaller in magnitude than a magnetic field strength in the second opening 920 (at a mid-point or center of the second opening 920). In an example, a first magnetic field 1710 is formed in the first opening 910 by at least a first current in the first electrical conductor 930 and/or the second electrical conductor 940. A second magnetic field 1720 is formed in the second opening 920 by at least a second current in the second electrical conductor 940 and/or third electrical conductor 950.

A chromatic aberration corrector, which may be described as having opposing electric and magnetic field forces, e.g. outward electric force and inward magnetic force, as may be understood from at least FIG. 7, are described further as follows. A first magnetic field force on a first portion of the charged particle beam is in an opposite direction to a first electric field force on the first portion of the charged particle beam. A second magnetic field force on the second portion of the charged particle beam is in an opposite direction to a second electric field force on the second portion of the charged particle beam. The aberration corrector 200 is configured for exerting a first electric field force on the first portion of the charged particle beam in a radially outwards direction. The aberration corrector 200 is configured for exerting a second electric field force on the second portion of the charged particle beam in a radially outwards direction.

In an embodiment, the aberration corrector 200 is configured for exerting a first magnetic field force on the first portion 2110 (see for example FIG. 7) of the charged particle beam is in a radially inwards direction. In an embodiment, the aberration corrector 200 is configured for exerting a second magnetic field force on the second portion 2120 (see for example FIG. 7) of the charged particle beam is in a radially inwards direction.

In an embodiment, a magnetic field 1710, 1720 of at least one of the first electrical conductor 930, the second electrical conductor 940 and/or the third electrical conductor 950 is in an anti-clockwise direction in a plane perpendicular to an axis 120 (e.g. of the charged particle beam, of the aberration corrector 200 or of the charged particle beam column 100), when viewed from above or upstream of the aberration corrector 200.

In an embodiment, a current in an electrical conductor of the plurality of electrical conductors 930, 940, 950 with the smallest radial position or a current in the first electrical conductor 930 is in a direction opposite to a propagation direction of the charged particle beam, and/or parallel to an axis of the aberration corrector 200, and/or towards a charged particle source 110.

In an embodiment, at least one electrical conductor of the plurality of electrical conductors 930, 940, 950 is at a less positive electric potential than at least one electrical conductor of the plurality of electrical conductors 930, 940, 950 in a radially further position.

In an embodiment, a first electric field is formed in the first opening 910 by at least the second electrical conductor 940 bounding the first opening 910 being at a positive electric potential and/or at a more positive electric potential than the first electrical conductor 930. A second electric field is formed in the second opening 920 by at least the third electrical conductor 950 bounding the second opening 920 being at a positive electric potential and/or at a more positive electric potential than the second electrical conductor 940.

A chromatic aberration corrector, which may be described to have a generalized form, including for example a grid form or a cylindrical form, as may be understood from at least FIG. 7, are described further as follows. FIG. 7 is a simplified representation of a chromatic aberration corrector according to aspects described herein.

According to an aspect, it is provided a charged particle beam chromatic aberration corrector 200 including a plurality of electrical conductors forming two or more openings including a first opening 2210 and a second opening 2220; and a power supply system 2800 configured for forming a first electric field 2310 and a first magnetic field 2510 in the first opening 2210; and a second electric field 2410 and a second magnetic field 2610 in the second opening 2220.

According to the aspect, the first opening 2210 is arranged for traversal of a first portion 2110 of the charged particle beam, and the second opening 2220 is arranged for traversal of a second portion 2120 of the charged particle beam; wherein a first electric field strength of the first electric field 2310 is different from a second electric field strength of the second electric field 2410, and wherein a first magnetic field strength of the first magnetic field 2510 is different from a second magnetic field strength of the second magnetic field 2610.

According to the aspect, the first magnetic field 2510 exerts a first magnetic field force 2520 on the first portion 2110 of the charged particle beam; the first electric field 2310 exerts a first electric field force 2320 on the first portion 2110 of the charged particle beam; the first magnetic field force 2520 is in an opposite direction to the first electric field force 2320. The second magnetic field 2610 exerts a second magnetic field force 2620 on the second portion 2120 of the charged particle beam; the second electric field 2410 exerting a second electric field force 2420 on the second portion 2120 of the charged particle beam; the second magnetic field force 2620 is in an opposite direction to the second electric field force 2420.

It may be understood that the triangular representation of the first opening 2210 and the second opening 2220 is merely an arbitrary choice of representation and is not intended to have a technical meaning and/or be limiting to a triangular form. Some exemplary aspects, embodiments and examples of a chromatic aberration corrector are described further as follows.

An aberration corrector 200 for a charged particle beam can include a grid of wires and an array of current loop forming wires. A grid of wires forms perpendicular line deflectors. The one or more line deflectors form electric field(s). In another example, an aberration corrector 200 for a charged particle beam comprises a plurality of hollow cylinders with each other. Wire and/or grid of wires can be of any electrically conducting material. For example, the current loop forming wire(s) is (are) of any electrically conducting material. For example, the cylinders are of any electrically conducting material.

A first electrical conductor and/or first wire forms a first boundary of the first opening 2210, and a second electrical conductor or a second wire forms a second boundary of the first opening 2210. In an example, the first electrical conductor and/or first wire is at a different electric potential from the second electrical conductor or second wire, such as to form a first electric field in the first opening 2210. A second electrical conductor and/or second wire forms a first boundary of the second opening, and a third electrical conductor or a third wire forms a second boundary of the second opening 2220. In an example, the second electrical conductor and/or second wire is at a different electric potential from the third electrical conductor or third wire, such as to form a second electric field in the second opening 2220.

A power supply system 2800 can hold a first conductor or a first wire at a first electric potential. A power supply system 2800 can hold a second conductor or a second wire at a second electric potential. A power supply system 2800 can hold a third conductor or a third wire at a third electric potential. In an example, a power supply system 2800 provides a first current to a first conductor. In another example, the power supply system 2800 provides a first current to a first current loop or first current loop forming conductor or first current loop forming wire. In an example, a power supply system 2800 provides a second current to a second conductor. In another example, the power supply system 2800 provides a second current to a second current loop or second current loop forming conductor or second current loop forming wire. In an example, a power supply system 2800 provides a third current to a third conductor. In another example, the power supply system 2800 provides a third current to a third current loop or third current loop forming conductor or third current loop forming wire.

In an embodiment, the first opening 2210 is bounded by at least two electrical conductors of the plurality of electrical conductors, which are at different electric potential to each other. The second opening 2220 is bounded by at least two electrical conductors of the plurality of electrical conductors, which are at different electric potential to each other. An electric potential difference or an electric potential difference per distance across the first opening 2210 can be different or smaller in magnitude than an electric potential difference or an electric potential difference per distance across the second opening 2220. A first electric field strength of the first electric field (across the first opening 2210) can be different or less or smaller in magnitude than a second electric field strength of the second electric field (across the second opening 2220). A current in an electrical conductor of the plurality of electrical conductors bounding the first opening 2210 can be different or less or smaller than a current in an electrical conductor of the plurality of electrical conductors bounding the second opening 2220. A current in the first electrical conductor and/or first wire bounding the first opening 2210 can be different or less or smaller than a current in the second electrical conductor and/or second wire and/or the third electrical conductor and/or third wire bounding the second opening 2220. In an embodiment, a first magnetic field strength of the first magnetic field (across the first opening 2210) is different or less or smaller in magnitude than a second magnetic field strength of the second magnetic field (across the second opening 2220).

According to some embodiments, a first electric field force 2320 (of the first electric field 2310) acts on a respective portion or a first portion 2110 of the charged particle beam traversing the first opening 2210. The first electric field force 2320 is formed by the difference in electric potential between the first electrical conductor or first wire and the second electrical conductor or second wire. In an example, the first electric field force 2320 is in a radially outwards direction. A first current loop (arranged proximate to the first opening 2210) is provided with a first current, such as to form a first magnetic field 2510 in the first opening 2210. A first conductor forming a first boundary of the first opening 2210 is provided with a first current, such as to form the first magnetic field 2510 in the first opening 2210. In an example, a plane of the first current loop is perpendicular to a plane of the first opening 2210. An axis of a plane of the first current loop can be parallel to a plane of the first opening 2210 or to a plane of the plurality of conductors or plurality of wires. In particular, an axis of a plane of the first current loop can be parallel to the first conductor or first wire. A first current loop can be a first current loop forming conductor or first current loop forming wire. The first current loop can be formed of any electrically conductive material.

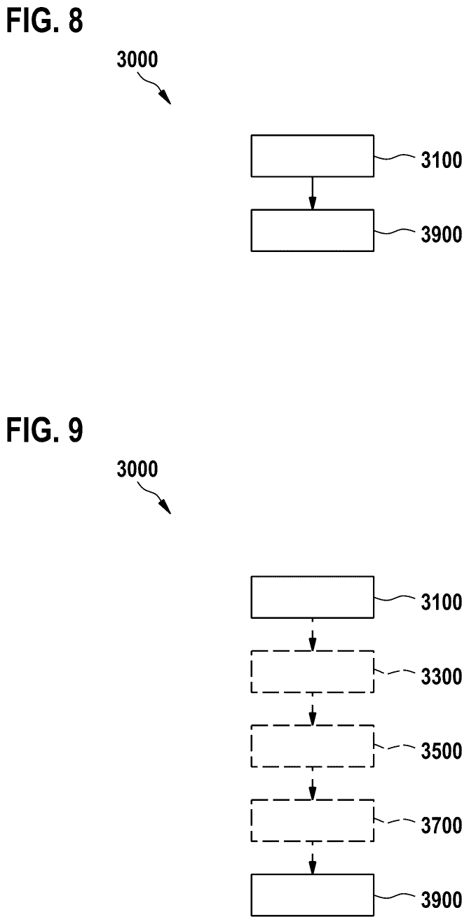

A method 3000 of correcting chromatic aberration of a charged particle beam as may be understood from at least FIG. 8 and FIG. 9, is described further as follows. FIG. 8 is a flow diagram of a method of correcting chromatic aberration of a charged particle beam according to aspects described herein.

According to an aspect, there is provided a method of correcting chromatic aberration of a charged particle beam using a corrector, the method including generating a respective one of a plurality of electric fields and a respective one a plurality of magnetic fields in each of the two or more openings 3100; and guiding the charged particle beam through the two or more openings 3900.

In an embodiment, the method includes reducing a spot size of the charged particle beam or increasing a current of the charged particle beam impinging on a sample. In an embodiment, the method includes performing at least one of the following: adjusting at least one of a first current to change a first magnetic field strength and/or adjusting at least one electric potential to change a first electric field strength 3300, adjusting a second current to change a second magnetic field strength and/or adjusting at least one electric potential to change a second electric field strength 3500, and adjusting at least one of a third current to change a third magnetic field strength and/or adjusting at least one electric potential current to change a third electric field strength 3700. Beneficially, an aberration, in particular, a chromatic aberration of the charged particle beam can be corrected.

Some further aspects, embodiments, examples, which may be described (in a non-limiting manner) as relating to micro-electromechanical systems (MEMS), are described further as follows. In an embodiment, each of the plurality of electrical conductors or plurality of wires have a diameter less than 10 μm, or less than 5 μm or less than 1 μm. In an embodiment, each of the plurality of electrical conductors or plurality of wires is of carbon nanotubes. Each of the plurality of electrical conductors or plurality of wires can be a micro-electromechanical systems MEMS structure and/or fabricated by micro-electromechanical systems manufacturing methods. For example, each of the plurality of electrical conductors or plurality of wires is fabricated on a wafer.

Beneficially, by using MEMS, the apparatus is scalable and has low costs per unit in mass fabrication. Beneficially, when implementing the aberration corrector as a MEMS structure, the electrical conductors or wires can easily be formed using silicon and/or metal, in particular, silicon covered with a metal (e.g. fully MEMS technology), or carbon nanowires and/or MEMS holder, e.g. carbon nanowires on a MEMS holder (e.g. in a case of partly MEMS technology). Beneficially, implementing the aberration corrector using MEMS allows for increased electrical conductor or wire density. Beneficially, high electrical conductor or wire density enables increased accuracy and control of aberration correction.

Further aspects, embodiments, examples and terminologies are described further as follows.

It may be understood that aspects, embodiments and examples disclosed herein with respect to the first opening, the first electrical conductor (bounding the first opening), the first wire (bounding the first opening), the second electrical conductor (bounding the first opening), the second wire (bounding the first opening), the first electric field (in or proximate to the first opening), the first current loop (proximate or adjacent to the first opening), the first current loop forming conductor (proximate or adjacent to the first opening), the first current loop forming wire (proximate or adjacent to the first opening), and/or the first magnetic field (in or proximate to the first opening), are also disclosed, mutatis mutandis, with respect to a second opening, a third electrical conductor, a third wire, a fourth electrical conductor, a fourth wire, a second electric field, a second current loop, a second current loop forming conductor, a second current loop forming wire, and a second magnetic field, and/or, mutatis mutandis, one or more further openings, electrical conductors, wires, electric fields, current loops, current loop forming conductors, current loop forming wires, and magnetic fields.

It may be understood that examples and embodiments as described herein, and relating to a first (e.g. opening, electrical conductor, wire, electric field, current loop forming wire, magnetic field), a second (e.g. opening, electrical conductor, wire, electric field, current loop forming wire, magnetic field) and further (e.g. opening, electrical conductor, wire, electric field, current loop forming wire, magnetic field), may differ by their radial position.

For example, the first, second and further may differ in radial position from an axis of or a center of the aberration corrector 200, from an axis of or a center of the charged particle beam, and/or from an axis of or a center of the charged particle beam column 100, in particular, in a radial direction and/or perpendicular to the respective axis or center. In an example, an axis or a direction of the first electric field 2310 in the first opening 2210 is perpendicular to an axis or a direction of the first magnetic field 2510 in the first opening 2210. An axis of or a direction of the first electric field 2310 can be perpendicular to an axis of the charged particle beam, of the aberration corrector 200 and/or the charged particle beam column 100. For example, an axis of or a direction of the first magnetic field 2510 is perpendicular to an axis of the charged particle beam, of the aberration corrector 200 and/or the charged particle beam column 100. An axis or a direction of the second electric field 2410 in the second opening 2220 is perpendicular to an axis or a direction of the second magnetic field 2610 in the second opening 2220. An axis of or a direction of the second electric field 2410 is perpendicular to an axis of the charged particle beam, of the aberration corrector 200 and/or the charged particle beam column 100. An axis of or a direction of the second magnetic field 2610 is perpendicular to an axis of the charged particle beam, of the aberration corrector 200 and/or the charged particle beam column 100.

A first portion 2110 of the charged particle beam and the second portion 2120 of the charged particle beam can be contiguous portions of the charged particle beam. In an example, at least one of the plurality of electrical conductors or a second electrical conductor separates the charged particle beam into the first portion 2110 of the charged particle beam and the second portion 2120 of the charged particle beam, in particular, as the charged particle beam traverses the aberration corrector 200.

In an embodiment, at least one or all of the following: the plurality of wires, the plurality of current loop forming wires is or are formed of any electrically conductive material.

A charged particle source may be understood as a charged particle source for emitting the charged particle beam or configured to emit the charged particle beam. A charged particle beam may be understood as a beam emitted from a charged particle source 110, and/or a primary charged particle beam. In an example, an axis of the aberration corrector 200 is coaxial or parallel to an axis 120 of the charged particle beam, or to an axis of the charged particle beam column 100.

The expressions ‘upstream’ and ‘downstream’ may be understood in reference to a propagation direction of the charged particle beam. The expressions ‘upstream’, ‘above’ and ‘before’ may be understood as closer to a charged particle source 110 of the charged particle beam column 100 or further from a sample 180 or sample stage 190, in particular, in a direction parallel to an axis 120 of the charged particle beam or to an axis of the charged particle beam column 100. The expressions ‘downstream’, ‘below’ and ‘after’ may be understood as closer to a sample 180 or sample stage 190 or further from a charged particle source 110 of the charged particle beam column 100, in particular, in a direction parallel to an axis 120 of the charged particle beam or to an axis of the charged particle beam column 100.

In an example, the expression ‘a first element is upstream/above/before of a second element’ may be understood as the first element being arranged closer to a charged particle source 110 of the charged particle beam column 100 than the second element and/or being arranged further from a sample 180 and/or sample stage 190 than the second element, in particular, in a direction parallel to an axis 120 of the charged particle beam and/or to an axis of the charged particle beam column 100. In an example, the expression ‘a first element is downstream/below/after of a second element’ may be understood as the first element being arranged further from a charged particle source 110 of the charged particle beam column 100 than the second element and/or being arranged closer to a sample 180 and/or sample stage 190 than the second element, in particular, in a direction parallel to an axis 120 of the charged particle beam and/or to an axis of the charged particle beam column 100.

The expressions ‘above’ and ‘below’ may be understood in reference to the aberration corrector 200 and/or along a direction parallel to an axis of the aberration corrector 200. The expressions ‘before’ and ‘after’ may be understood in reference to a propagation direction of the charged particle beam.

The expression ‘radial position’ may be understood as a position in a radial direction from an axis of or a center of the plurality of electrical conductors 930, 940, 950, an axis of or a center of the plurality of wires an axis of or a center of the aberration corrector 200, an axis of or a center of the charged particle beam, and/or an axis of or a center of the charged particle beam column 100, in particular, in a radial direction and/or perpendicular to the respective axis or center.

The term ‘distance’, for example, ‘a distance between two electrical conductors bounding an opening’, ‘a distance between at least two wires bounding an opening’, ‘an electric potential difference per distance’, may be understood as a distance along or parallel to a radial direction from an axis of or a center of the plurality of electrical conductors 930, 940, 950, an axis of or a center of the plurality of wires, an axis of or a center of the aberration corrector 200, an axis of or a center of the charged particle beam, and/or an axis of or a center of the charged particle beam column 100.

The expression ‘stronger’ or ‘weaker’ may be understood as a scalar difference or relative difference in magnitude, in particular irrespective of sign or direction. The expression ‘opposite direction’ may be understood as having an angle therebetween of 160 to 200 degrees, or 170 to 190 degrees, or 175 to 185 degrees.

The expression ‘propagation direction of the charged particle beam’ may be understood as along or parallel to a direction from a charged particle source to a sample 180, or a focal point on a sample 180, or to a sample stage 190.

The expression ‘radially inward’ may be understood as facing towards or arranged closer to an axis of or a center of the plurality of electrical conductors 930, 940, 950, an axis of or a center of the plurality of wires an axis of or a center of the aberration corrector 200, an axis of or a center of the charged particle beam, and/or an axis of or a center of the charged particle beam column 100, in particular, in a radial direction and/or perpendicular to the respective axis or center. The expression ‘radially outwards’ may be understood to be away from an axis of or a center of the plurality of electrical conductors 930, 940, 950, an axis of or a center of the plurality of wires an axis of or a center of the aberration corrector 200, an axis of or a center of the charged particle beam, and/or an axis of or a center of the charged particle beam column 100, in particular, in a radial direction and/or perpendicular to the respective axis or center.

The expression ‘an axis of a plane’ may be understood as an axis normal to the plane. An axis of the first opening 2210 may be understood as an axis normal to a plane of the first opening 2210. An axis of the second opening 2220 may be understood as an axis normal to a plane of the second opening 2220. An axis of the first current loop forming wire 810 may be understood as an axis normal to a plane of the first current loop forming wire 810. An axis of the second current loop forming wire may be understood as an axis normal to a plane of the second current loop forming wire.

The expression ‘reducing a spot size’ may be understood as a scalar reduction or reduction in magnitude, in particular, irrespective of sign or direction.

The expression ‘increasing a current’ may be understood as a scalar increase or increase in magnitude, in particular, irrespective of sign or direction.

A ‘wire’ or ‘a plurality of wires’ may be understood being of any electrically conducting material, for example metal (e.g. copper), and/or carbon (e.g. carbon nanotubes).

An aberration corrector may be understood as a charged particle beam chromatic aberration corrector or an aberration corrector for a charged particle beam. An aberration corrector may be understood as a corrector for correcting an aberration of a charged particle beam. An aberration corrector may be understood as a chromatic aberration corrector. An aberration corrector may be understood as a corrector for correcting a chromatic aberration.

Some further technical aspects, embodiments and examples of a chromatic aberration corrector, which may be considered optional and/or non-limiting, are described further as follows.

A coaxial wire can produce the necessary fields to act as a radial Wien Filter (Hφ and Er). Voltage and current can be controlled to adjust the electric field, E and magnetic field, H independently. The phase shift between the electrodes may vary logarithmically. For a Wien Filter deflector for chromatic aberration correction, several coaxial cylinders with radially increasing voltages and currents can be used.

A cylindrical configuration may be simpler as compared to a grid configuration since the cylindrical electrodes carrying currents can simultaneously create the required electric and magnetic fields. As described herein, deflector arrays may be used for chromatic aberration correction. A combination of line deflectors (electric field) and small current loops (magnetic field) can be built to produce a Wien Filter deflector array to thereby correct chromatic aberration.

A Wien Filter deflector array (e.g. two arrays in X and Y) can be used to create a negative chromatic aberration (compared with conventional round lenses), for example, by defocusing the slower electrons and focusing the faster electrons. For the optimal magnetic field distribution, the array of small current loops can be such that the magnetic field, B increases from the centre. Thus, an array of Wien Filter deflectors can be used to correct chromatic aberrations.

Using micro-electromechanical systems, MEMS, an array of Wien Filter deflectors would be relatively cheap to build. Further, there would be less complexity (also in alignment) compared with a multipole corrector.

In general, the electronics requirements of a chromatic aberration corrector as described herein are lower compared to a conventional aberration corrector. Correcting chromatic aberrations of electron beam system can lead to an improvement in resolution, especially in workpoints with low landing energy, which are mainly dominated by chromatic aberration, Cc.

Enabling a cost-effective aberration corrector would enable the implementation in different tools, especially for tools with lower requirements. For example, it would be particularly beneficial for tools such as a Critical Dimension Scanning Electron Microscope (CD-SEM), for extreme ultra-violet (EUV) resist inspection for example.

Examples described herein having no on-axis conductor, e.g. wire, does not block an on-axis portion of the beam. Further, such a device may be much shorter in length. The benefits are particularly significant at high beam currents where electron-electron interaction affect performance.

While the foregoing is directed to embodiments, other and further embodiments may be devised without departing from the basic scope, and the scope thereof is determined by the claims that follow.

1. A charged particle beam chromatic aberration corrector comprising:
a plurality of electrical conductors forming a segmented Wien filter including a plurality of Wien filter segments having at least a first Wien filter segment and a second Wien filter segment, wherein the first Wien filter segment is arranged for traversal of a first portion of the charged particle beam, and the second Wien filter segment is arranged for traversal of a second portion of the charged particle beam; and
a power supply system configured for generating different electric fields and different magnetic fields for the first Wien filter segment and second Wien filter segment.

2. The charged particle beam chromatic aberration corrector according to claim 1, wherein the plurality of Wien filter segments each comprise a first region having a magnetic field, a second region comprising an electric field, wherein the electric field act in an opposite direction as the magnetic field.

3. The charged particle beam chromatic aberration corrector according to claim 2, wherein the first region is provided at a different position along an optical axis than the second region.

4. The charged particle beam chromatic aberration corrector according to claim 1, wherein a first electric field strength of the first Wien filter segment is different from a second electric field strength of the second Wien filter segment, and wherein a first magnetic field strength of the first Wien filter segment is different from a second magnetic field strength of the second Wien filter segment.

5. The corrector according to claim 4, wherein at least one of the following is provided:
the first electric field is perpendicular to the first magnetic field, the first electric field is perpendicular to an axis of the charged particle beam, and the first magnetic field is perpendicular to an axis of the charged particle beam; and
the second electric field is perpendicular to the second magnetic field, the second electric field is perpendicular to an axis of the charged particle beam, and the second magnetic field is perpendicular to an axis of the charged particle beam.

6. The corrector according to claim 4, wherein at least one of the following is provided:
a first opening corresponding to the first Wien filter segment is at a different or smaller distance from a center of the corrector than a second opening corresponding to the second Wien filter segment; and
the first opening is bounded by at least two electrical conductors of the plurality of electrical conductors, which are at different electric potential to each other, and the second opening is bounded by at least two electrical conductors of the plurality of electrical conductors, which are at different electric potential to each other.

7. The corrector according to claim 6, wherein an electric potential difference or an electric potential difference per distance across the first opening is different or smaller in magnitude than an electric potential difference or an electric potential difference per distance across the second opening; or the first electric field strength is smaller in magnitude than the second electric field strength.

8. The corrector according to claim 1, wherein a current in the first Wien filter segment is different or smaller than a current in second Wien filter segment.

9. A charged particle beam chromatic aberration corrector comprising:
a first set of wires forming two or more openings including a first opening in a first Wien filter segment and a second opening in a second Wien filter segment, at least the first Wien filter segment and the second Wien filter segment forming a first segmented Wien filter for a charged particle beam, wherein the first opening is arranged for traversal of a first portion of the charged particle beam, and the second opening is arranged for traversal of a second portion of the charged particle beam; and
a first set of current loop forming wires including a first current loop forming wire of the first Wien filter segment and a second current loop forming wire of the second Wien filter segment.

10. The charged particle beam chromatic aberration corrector according to claim 9, further comprising: a second set of wires and a second set of current loop forming wires, which form a second segmented Wien filter, wherein Wien filter segments of the first segmented Wien filter are configured to generate dispersion in a first direction and Wien filter segments of the second segmented Wien filter are configured to generate dispersion in a second direction different than the first direction.

11. The charged particle beam chromatic aberration corrector according to claim 9, wherein the first opening is at a different or smaller distance from a center of the corrector than the second opening or wherein the first opening is bounded by at least two wires of the first et of wires, which are at different electric potential to each other, and the second opening is bounded by at least two wires of the first set of wires, which are at different electric potential to each other.

12. The charged particle beam chromatic aberration corrector according to claim 9, wherein the first Wien filter segment and the second Wien filter segment have different electric field strengths and different magnetic field strengths, or wherein a wire of the first Wien filter segment is at a less positive potential than a wire of the second Wien filter segment.

13. A charged particle beam chromatic aberration corrector, comprising:
a plurality of electrical conductors forming two or more openings including a first opening in a first Wien filter segment and a second opening in a second Wien filter segment;
wherein a first electrical conductor and a second electrical conductor of the plurality of electrical conductors extend in a direction perpendicular to a plane of the first opening and the second opening; and
wherein the first Wien filter segment is arranged for traversal of a first portion of a charged particle beam through the first opening and the second Wien filter segment is arranged for traversal of a second portion of the charged particle beam through the second opening;
wherein the first electrical conductor bounds the first opening and the second electrical conductor bounds the second opening.

14. The charged particle beam chromatic aberration corrector according to claim 13, further comprising a central opening or wherein at least one of the following is provided:
at least one of the plurality of electrical conductors has a hollow cylindrical form;
each of the plurality of electrical conductors is coaxial with each other; and
each of the plurality of electrical conductors is coaxial with an axis of the charged particle beam.

15. The charged particle beam chromatic aberration corrector according to claim 13, wherein at least one of the following is provided:
the first opening is at a different or smaller radial position than the second opening;
the first opening is bounded by at least two electrical conductors of the plurality of electrical conductors and the second opening is bounded by at least two electrical conductors of the plurality of electrical conductors, which are at different electric potential to each other;
an electric potential difference or an electric potential difference per distance across the first opening is different or smaller in magnitude than an electric potential difference or an electric potential difference per distance across the second opening or a first electric field across the first opening is different or weaker than a second electric field across the second opening; and
a current in the first electrical conductor is different or smaller than a current in the second electrical conductor or a first magnetic field across the first opening is different or weaker than a second magnetic field across the second opening.

16. The charged particle beam chromatic aberration corrector according to claim 13, wherein at least one of the following is provided:
a first magnetic field is formed in the first opening by at least a first current in the first electrical conductor, and a first electric field is formed in the first opening by at least the first electrical conductor bounding the first opening being at a positive electric potential and a first magnetic field force on the first portion of the charged particle beam is in an opposite direction to a first electric field force on the first portion of the charged particle beam; and
a second magnetic field is formed in the second opening by at least a second current in the second electrical conductor, and a second electric field is formed in the second opening by at least an electric potential difference between at least two electrical conductors of the plurality of electrical conductors bounding the second opening and a second magnetic field force on the second portion of the charged particle beam is in an opposite direction to a second electric field force on the second portion of the charged particle beam.

17. The charged particle beam chromatic aberration corrector according to claim 13, wherein the first Wien filter segment and the second Wien filter segment have different electric field strength and different magnetic field strength, or wherein a conductor of the first Wien filter segment is at a less positive potential than a conductor of the second Wien filter segment.

18. The charged particle beam chromatic aberration corrector according to claim 13, wherein at least one of the following is provided:
a magnetic field of at least one of the first electrical conductor and the second electrical conductor is in an anti-clockwise direction when viewed from above or upstream of the corrector; and
the corrector is configured for exerting a first magnetic field force on the first portion of the charged particle beam is in a radially inwards direction and the corrector is configured for exerting a second magnetic field force on the second portion of the charged particle beam is in a radially inwards direction.

19. A method of correcting chromatic aberration of a charged particle beam using a corrector according to claim 1, the method comprising:
generating a respective one of a plurality of electric fields and a respective one a plurality of magnetic fields in each of the two or more openings; and
guiding the charged particle beam through the two or more openings.

20. The method according to claim 19, further comprising reducing a spot size of the charged particle beam or increasing a current density of the charged particle beam impinging on a sample, by adjusting a first current to change a first magnetic field strength and adjusting a second current to change a second magnetic field strength.
